(19) United States
(12) Patent Application Publication
(10) Pub. No.: US 2026/0090244 A1
(43) Pub. Date: Mar. 26, 2026

(54) DISPLAY PANEL, PREPARATION METHOD FOR DISPLAY PANEL, AND DISPLAY DEVICE

(71) Applicants: Hefei Visionox Technology Co., Ltd., Hefei (CN); Visionox Technology Inc., Kunshan (CN)

(72) Inventors: Zhiwei ZHOU, Hefei (CN); Qingfeng XU, Hefei (CN); Wenyu ZENG, Hefei (CN); Lu ZHANG, Kunshan (CN)

(73) Assignees: Hefei Visionox Technology Co., Ltd., Hefei (CN); Visionox Technology Inc., Kunshan (CN)

(21) Appl. No.: 19/331,972

(22) Filed: Sep. 17, 2025

(30) Foreign Application Priority Data
Sep. 20, 2024 (CN) 202411329526.4

(51) Int. Cl. H10K 59/80; H01L 25/075; H10H 20/01; H10H 20/831; H10H 20/853; H10K 102/00

(52) U.S. Cl. CPC H10K 59/873; H10H 20/032; H10H 20/0362; H10H 20/831; H10H 20/853; H10K 59/80521; H10W 90/00; H10K 2102/351

(57) ABSTRACT

The present application discloses a display panel, a preparation method for a display panel, and a display device. The display panel includes a substrate, an isolation structure, a light-emitting layer, first electrodes, and a first encapsulation layer. The isolation structure is arranged on a side of the substrate and encloses isolation openings. The light-emitting layer includes light-emitting units at least partially located within the isolation openings. The first electrodes are arranged on a side of the light-emitting units facing away from the substrate, a first electrode overlapping with a first isolation portion. The first encapsulation layer includes encapsulation portions located on a side of the first electrodes facing away from the substrate, each encapsulation portion including a first sub-portion formed of an inorganic material, the first sub-portion covering the first electrode, and the first sub-portions of at least two of the encapsulation portions having different thicknesses.

### CROSS REFERENCE

The present disclosure claims priorities to Chinese Patent Application No. 202411329526.4 titled “DISPLAY PANEL, PREPARATION METHOD FOR DISPLAY PANEL, AND DISPLAY DEVICE” filed on Sep. 20, 2024, which is incorporated herein by reference in its entirety.

### FIELD

The present application relates to the field of display technology, and in particular, to a display panel, a preparation method for a display panel, and a display device.

### BACKGROUND

Organic light emitting diodes (OLEDs) as well as flat panel display devices based on technologies such as light emitting diodes (LEDs) have been widely applied in various consumer electronics such as mobile phones, televisions, laptop computers, and desktop computers due to their advantages such as high image quality, energy efficiency, slim design, and wide applications, making them mainstream in display devices.

However, the usage performance of conventional OLED display products needs to be improved.

### SUMMARY

An object of the present application is to provide a display panel, a preparation method for a display panel, and a display device, which can improve the performance of the display panel.

One embodiment of the present application provides a display panel, including a substrate, an isolation structure, a light-emitting layer, and a first encapsulation layer, where the isolation structure is arranged on a side of the substrate and encloses isolation openings; the light-emitting layer includes light-emitting units located within the isolation openings; first electrodes are provided on a side of the light-emitting units facing away from the substrate, a first electrode overlapping with a first isolation portion; and the first encapsulation layer includes encapsulation portions located on a side of the first electrodes facing away from the substrate, each encapsulation portion including a first sub-portion formed of an inorganic material, the first sub-portion covering the first electrode, and the first sub-portions of at least two of the encapsulation portions having different thicknesses.

In some embodiments, each encapsulation portion includes at least the first sub-portion and a second sub-portion, the second sub-portion covering the first sub-portion.

The second sub-portion has a thickness greater than the thickness of the first sub-portion.

In one embodiment, the isolation structure includes the first isolation portion and a second isolation portion arranged on a side of the first isolation portion facing away from the substrate, an orthographic projection of the first isolation portion on the substrate being located within an orthographic projection of the second isolation portion on the substrate.

In one embodiment, a gap is formed between a side of the first sub-portion facing away from the substrate and a side of the second isolation portion facing the substrate, and the gap is filled with the second sub-portion.

In one embodiment, the first sub-portion has a density different from a density of the second sub-portion.

In one embodiment, the density of the first sub-portion is greater than the density of the second sub-portion, or the density of the first sub-portion is less than the density of the second sub-portion.

In one embodiment, the first sub-portion and/or the second sub-portion include(s) a silicon-containing inorganic material.

In some embodiments, the second sub-portion extends to a side of the second isolation portion facing away from the substrate via a sidewall of the second isolation portion facing an isolation opening.

In one embodiment, the first sub-portion includes a first segment, a second segment, and a third segment, the first segment being located on a side of the first electrode facing away from the substrate, the second segment being located on a side of the first isolation portion facing the isolation opening, and the third segment being located between the sidewall of the second isolation portion facing the isolation opening and the second sub-portion.

In one embodiment, the third segment further extends to the side of the second isolation portion facing away from the substrate.

In some embodiments, each encapsulation portion further includes a third sub-portion, the third sub-portion covering the second sub-portion.

In one embodiment, the third sub-portion extends to the side of the second isolation portion facing away from the substrate.

In one embodiment, the third sub-portion includes a fourth segment and a fifth segment, an orthographic projection of the fourth segment on the substrate being located within an orthographic projection of the first electrode on the substrate, the fifth segment extending from an edge of the fourth segment to the side of the second isolation portion facing away from the substrate, and at least part of the fourth segment protruding relative to the first isolation portion in a direction away from the substrate.

In one embodiment, the first sub-portion has a density greater than the density of the second sub-portion, and the third sub-portion has a density greater than the density of the second sub-portion.

In one embodiment, the third sub-portion has a density greater than or equal to the density of the first sub-portion.

In one embodiment, the third sub-portion includes a silicon-containing inorganic material.

In some embodiments, the light-emitting units include a first light-emitting unit, a second light-emitting unit, and a third light-emitting unit; the encapsulation portions include a first encapsulation portion, a second encapsulation portion, and a third encapsulation portion; and the first encapsulation portion is configured to encapsulate the first light-emitting unit, the second encapsulation portion is configured to encapsulate the second light-emitting unit, and the third encapsulation portion is configured to encapsulate the third light-emitting unit.

In one embodiment, the third sub-portion of the first encapsulation portion has a thickness greater than or equal to a thickness of the third sub-portion of the second encapsulation portion, and/or the third sub-portion of the second encapsulation portion has a thickness greater than a thickness of the third sub-portion of the third encapsulation portion.

In one embodiment, the first encapsulation portion has a thickness greater than a thickness of the second encapsulation portion, and the second encapsulation portion has a thickness greater than a thickness of the third encapsulation portion.

In some embodiments, the light-emitting units include a first light-emitting unit, a second light-emitting unit, and a third light-emitting unit; the encapsulation portions include a first encapsulation portion, a second encapsulation portion, and a third encapsulation portion; and the first encapsulation portion is configured to encapsulate the first light-emitting unit, the second encapsulation portion is configured to encapsulate the second light-emitting unit, and the third encapsulation portion is configured to encapsulate the third light-emitting unit, where at least two of the first sub-portion of the first encapsulation portion, the first sub-portion of the second encapsulation portion, and the first sub-portion of the third encapsulation portion have different thicknesses.

In some embodiments, the thickness of the first sub-portion of the first encapsulation portion and/or of the first sub-portion of the second encapsulation portion is less than a thickness of the first isolation portion.

In one embodiment, a ratio Z1 of the thickness of the first sub-portion of the first encapsulation portion and/or of the first sub-portion of the second encapsulation portion to the thickness of the first isolation portion satisfies: 0.05≤Z1<1.

In some embodiments, the thickness of the first sub-portion of the third encapsulation portion is greater than the thickness of the first sub-portion of the first encapsulation portion and/or of the first sub-portion of the second encapsulation portion.

In one embodiment, a ratio Z2 of the thickness of the first sub-portion of the third encapsulation portion to the thickness of the first sub-portion of the first encapsulation portion and/or of the first sub-portion of the second encapsulation portion satisfies: 1<Z2≤12.

In one embodiment, the thickness of the first sub-portion of the first encapsulation portion is less than or equal to the thickness of the first sub-portion of the second encapsulation portion.

In some embodiments, a ratio Z3 of the thickness of the first sub-portion of the third encapsulation portion to the thickness of the first isolation portion satisfies: 0.1<Z3≤1.2.

In one embodiment, the thickness of the first sub-portion of the third encapsulation portion is greater than or equal to the thickness of the first isolation portion.

In some embodiments, a thickness H1 of the first sub-portion of the first encapsulation portion and/or of the first sub-portion of the second encapsulation portion satisfies: 500 angstroms≤H1≤5000 angstroms.

In one embodiment, the thickness H2 of the first sub-portion of the third encapsulation portion satisfies: 1000 angstroms≤H2≤6000 angstroms.

In one embodiment, the thickness H3 of the first isolation portion satisfies: 5000 angstroms≤H3<10000 angstroms.

In some embodiments, a material of the first isolation portion includes a conductive material.

In one embodiment, a material of the second isolation portion includes a conductive material.

In one embodiment, the isolation structure further includes a third isolation portion located on a side of the first isolation portion facing the substrate.

In some embodiments, the display panel further includes a second encapsulation layer arranged on a side of the first encapsulation layer facing away from the substrate.

In one embodiment, the second encapsulation layer includes an organic material.

In one embodiment, the display panel further includes a third encapsulation layer arranged on a side of the second encapsulation layer facing away from the substrate.

In one embodiment, the third encapsulation layer includes an inorganic material.

One embodiment of the present application provides a preparation method for a display panel, including:
forming an isolation structure on a side of a substrate, where the isolation structure encloses isolation openings, and the isolation structure includes a first isolation portion and a second isolation portion arranged on a side of the first isolation portion facing away from the substrate, an orthographic projection of the first isolation portion on the substrate being located within an orthographic projection of the second isolation portion on the substrate; and
forming, in the isolation openings, light-emitting units and encapsulation portions configured to encapsulate the light-emitting units, where each light-emitting unit includes a first electrode overlapping with the first isolation portion, and each encapsulation portion includes at least a first sub-portion and a second sub-portion, the first sub-portion covering the first electrode, the second sub-portion covering the first sub-portion, the first sub-portion having a density different from a density of the second sub-portion, and the first sub-portions of at least two of the encapsulation portions having different thicknesses.

In some embodiments, forming, in the isolation openings, light-emitting units and the encapsulation portions configured to encapsulate the light-emitting units includes:
sequentially forming a first light-emitting material layer, a first sub-encapsulation material layer, and a second sub-encapsulation material layer on a side of the isolation structure facing away from the substrate;
patterning the first light-emitting material layer, the first sub-encapsulation material layer, and the second sub-encapsulation material layer to form a first light-emitting unit and a first encapsulation portion, where the first encapsulation portion includes a first sub-portion and a second sub-portion, the first sub-portion covering the first electrode, the second sub-portion covering the first sub-portion, and the first sub-portion having a density different from a density of the second sub-portion;
sequentially forming a second light-emitting material layer, a first sub-encapsulation material layer, and a second sub-encapsulation material layer on the side of the isolation structure facing away from the substrate;
patterning the second light-emitting material layer, the first sub-encapsulation material layer, and the second sub-encapsulation material layer to form a second light-emitting unit and a second encapsulation portion, where the second encapsulation portion includes a first sub-portion and a second sub-portion, the first sub-portion covering the first electrode, the second sub-portion covering the first sub-portion, and the first sub-portion having a density different from a density of the second sub-portion;
sequentially forming a third light-emitting material layer, a first sub-encapsulation material layer, and a second sub-encapsulation material layer on the side of the isolation structure facing away from the substrate; and
patterning the third light-emitting material layer, the first sub-encapsulation material layer, and the second sub-encapsulation material layer to form a third light-emitting unit and a third encapsulation portion, where the third encapsulation portion includes a first sub-portion and a second sub-portion, the first sub-portion covering the first electrode, the second sub-portion covering the first sub-portion, and the first sub-portion having a density different from a density of the second sub-portion.

In some embodiments, thicknesses of the first sub-encapsulation material layers corresponding to the first light-emitting material layer and the second light-emitting material layer are less than a thickness of the first sub-encapsulation material layer corresponding to the third light-emitting material layer.

In some embodiments, sequentially forming the first light-emitting material layer, the first sub-encapsulation material layer, and the second sub-encapsulation material layer on the side of the isolation structure facing away from the substrate further includes:
forming a third sub-encapsulation material layer on a side of the second sub-encapsulation material layer facing away from the substrate;
patterning the first light-emitting material layer, the first sub-encapsulation material layer, and the second sub-encapsulation material layer to form the first light-emitting unit and the first encapsulation portion further includes:
patterning the third sub-encapsulation material layer to form a third sub-portion located on a side of the second sub-portion facing away from the substrate;
sequentially forming the second light-emitting material layer, the first sub-encapsulation material layer, and the second sub-encapsulation material layer on the side of the isolation structure facing away from the substrate further includes:
forming a third sub-encapsulation material layer on a side of the second sub-encapsulation material layer facing away from the substrate;
patterning the second light-emitting material layer, the first sub-encapsulation material layer, and the second sub-encapsulation material layer to form the second light-emitting unit and the second encapsulation portion further includes:
patterning the third sub-encapsulation material layer to form a third sub-portion located on a side of the second sub-portion facing away from the substrate;
sequentially forming the third light-emitting material layer, the first sub-encapsulation material layer, and the second sub-encapsulation material layer on the side of the isolation structure facing away from the substrate further includes:
forming a third sub-encapsulation material layer on a side of the second sub-encapsulation material layer facing away from the substrate; and
patterning the third light-emitting material layer, the first sub-encapsulation material layer, and the second sub-encapsulation material layer to form the third light-emitting unit and the third encapsulation portion further includes:
patterning the third sub-encapsulation material layer to form a third sub-portion located on a side of the second sub-portion facing away from the substrate.

In some embodiments, thicknesses of the third sub-encapsulation material layers corresponding to the first light-emitting material layer and the second light-emitting material layer are greater than a thickness of the third sub-encapsulation material layer corresponding to the third light-emitting material layer.

One embodiment of the present application provides a display device, including a display panel according to any one of the above embodiments or a display panel prepared by a preparation method according to any one of the above embodiments.

The present application provides a display panel, a preparation method for a display panel, and a display device. The display panel includes a substrate, an isolation structure, a light-emitting layer, and a first encapsulation layer, where the isolation structure is arranged on a side of the substrate and encloses isolation openings, and the isolation structure includes a first isolation portion and a second isolation portion arranged on a side of the first isolation portion facing away from the substrate, an orthographic projection of the first isolation portion on the substrate being located within an orthographic projection of the second isolation portion on the substrate. Therefore, the light-emitting material can be isolated by the second isolation portion to form light-emitting units, allowing the light-emitting units to be located within the isolation openings without the need for a mask, thereby reducing costs. Each light-emitting unit includes a first electrode overlapping with the first isolation portion, enabling the first electrodes of the light-emitting units to be electrically connected via the first isolation portion to form a full-area electrode. The first encapsulation layer includes encapsulation portions located on a side of the first electrodes facing away from the substrate to encapsulate the light-emitting units. Each encapsulation portion includes at least a first sub-portion and a second sub-portion. The first sub-portion covers the first electrode to encapsulate the corresponding light-emitting unit. The second sub-portion is located on a side of the first sub-portion facing away from the substrate to cover the first sub-portion. Therefore, the light-emitting unit can be further encapsulated by the second sub-portion. The density of the first sub-portion is different from the density of the second sub-portion, and by reasonably adjusting a density relationship between the first sub-portion and the second sub-portion, the performance of the encapsulation portion can be improved. In addition, the first sub-portions of at least two of the encapsulation portions have different thicknesses. During preparation of the light-emitting units and the encapsulation portions, the light-emitting unit and the encapsulation portion corresponding to the first sub-portion with the minimum thickness can be preferentially prepared. This reduces the contact area between the material of the first sub-portion of the previously prepared encapsulation portion and the sidewall of the first isolation portion facing the isolation opening, or even prevents contact between the material of the first sub-portion and the sidewall of the first isolation portion. Consequently, when subsequently etching and removing the material of the first sub-portion within part of the isolation openings, it is easier to etch and remove the material of the first sub-portion within the part of the isolation openings, thereby reducing the risk of the material of the first sub-portion remaining on the sidewall of the first isolation portion corresponding to the part of the isolation openings and thus improving the overlap yield between the first electrodes of subsequently prepared light-emitting units and the corresponding first isolation portion.

### BRIEF DESCRIPTION OF THE DRAWINGS

In order to describe the embodiments of the present application more clearly, the drawings required for illustration of the embodiments of the present application will be briefly introduced below. The drawings as described below are only for some of the embodiments of the present application.

FIG. 1 is a schematic cross-sectional view of a display panel according to some embodiments of the present application;

FIG. 2 is another schematic cross-sectional view of a display panel according to some embodiments of the present application;

FIG. 3 is a schematic cross-sectional view of a display panel according to other embodiments of the present application;

FIG. 4 is a schematic cross-sectional view of a display panel according to still other embodiments of the present application;

FIG. 5 is a flowchart of a preparation method for a display panel according to some embodiments of the present application; and

FIG. 6 is another flowchart of a preparation method for a display panel according to some embodiments of the present application.

### LIST OF REFERENCE SIGNS

100. Display panel; 10. Substrate; 20. Isolation structure; 21. Isolation opening; 22. First isolation portion; 23. Second isolation portion; 30. Light-emitting unit; 301. First light-emitting unit; 302. Second light-emitting unit; 303. Third light-emitting unit; 31. First electrode; 32. Light-emitting functional layer; 33. Second electrode; 40. Encapsulation portion; 401. First encapsulation portion; 402. Second encapsulation portion; 403. Third encapsulation portion; 41. First sub-portion; 411. First segment; 412. Second segment; 413. Third segment; 42. Second sub-portion; 43. Third sub-portion; 431. Fourth segment; 432. Fifth segment; 50. Second encapsulation layer; 60. Third encapsulation layer.

### DETAILED DESCRIPTION OF THE EMBODIMENTS

The embodiments of the present application are further described in detail below with reference to the drawings and embodiments. The following detailed description of the embodiments and the drawings are used to illustrate the principle of the present application by way of example, but shall not be used to limit the scope of the present application. That is, the present application is not limited to the described embodiments.

In the description of the present application, it should be noted that “a plurality of” means two or more, unless otherwise specified. The orientation or position relationship indicated by the terms “upper”, “lower”, “left”, “right”, “inner”, “outer”, etc. is merely for the convenience of describing the present application and simplifying the description, rather than indicating or implying that a device or element referred to must have a particular orientation or be constructed and operated in a particular orientation, and therefore should not be construed as limiting the present application. In addition, the terms “first”, “second”, “third”, etc., are merely for descriptive purposes and should not be construed as indicating or implying relative importance. The term “perpendicular” does not mean being perpendicular in the strict sense, but within an allowable range of tolerance. The term “parallel” does not mean being parallel in the strict sense, but within an allowable range of tolerance.

The phrase “embodiment” mentioned in the present application means that the specific features, structures and characteristics described with reference to the embodiment may be encompassed in at least one embodiment of the present application. This phrase in various places in the specification does not necessarily refer to the same embodiment or an independent or alternative embodiment exclusive of other embodiments. It should be understood explicitly and implicitly that the embodiments described in the present application may be combined with other embodiments.

The orientation terms in the following description all indicate directions shown in the accompanying drawings, and do not limit the specific structure in the present application. In the description of the present application, it should be noted that the terms “mount”, “connected”, or “connect” should be interpreted in a broad sense unless explicitly defined and limited otherwise. For example, they may be a fixed connection, a detachable connection, or an integral connection; or may be a direct connection, or an indirect connection by means of an intermediate medium. The specific meanings of the terms mentioned above in the present application may be construed according to specific circumstances.

The embodiments of the present application provide a display panel. The display panel may be an organic light emitting diode (OLED) display panel or other types of display panels, such as a micro light emitting diode (Micro-LED) display panel or a quantum light emitting diode (QLED) display panel.

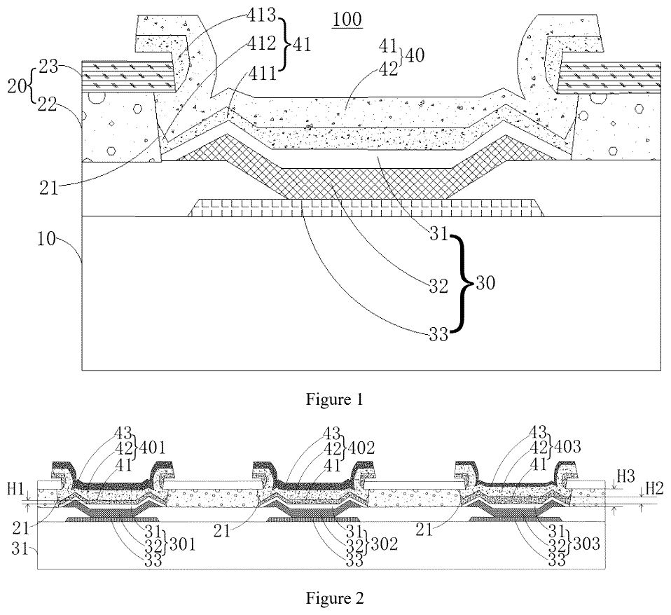

Referring to FIGS. 1 and 2, one embodiment of the present application provides a display panel 100, including a substrate 10, an isolation structure 20, a light-emitting layer, and a first encapsulation layer. The isolation structure 20 is arranged on a side of the substrate 10 and encloses isolation openings 21, and the isolation structure 20 includes a first isolation portion 22 and a second isolation portion 23 arranged on a side of the first isolation portion 22 facing away from the substrate 10, an orthographic projection of the first isolation portion 22 on the substrate 10 being located within an orthographic projection of the second isolation portion 23 on the substrate 10. The light-emitting layer includes light-emitting units 30 located within the isolation openings 21. First electrodes 31 are provided on a side of the light-emitting units 30 facing away from the substrate 10, a first electrode 31 overlapping with the first isolation portion 22. The first encapsulation layer includes encapsulation portions 40 located on a side of the first electrodes 31 facing away from the substrate 10. Each encapsulation portion 40 includes at least a first sub-portion 41 and a second sub-portion 42, the first sub-portion 41 covering the first electrode 31, the second sub-portion 42 covering the first sub-portion 41, the first sub-portion 41 having a density different from a density of the second sub-portion 42, and the first sub-portions 41 of at least two of the encapsulation portions 40 having different thicknesses.

The substrate 10 includes a base and a drive circuit layer arranged on the base. The base may be a rigid base made of glass, plastic, etc., or a flexible base made of polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), cellulose acetate propionate (CAP), etc. A drive circuit for controlling the light-emitting units 30 to emit light is provided in the drive circuit layer. The drive circuit layer is generally composed of inorganic film layers such as a metal layer, a semiconductor layer (active layer), and an insulation layer. The drive circuit for controlling the light-emitting units 30 to emit light may be formed by patterning these inorganic film layers, and there may be various embodiments of the specific circuit structure of the drive circuit, which will not be described in detail herein.

The isolation structure 20 encloses the isolation openings 21, and the isolation structure 20 includes the first isolation portion 22 and the second isolation portion 23 arranged on the side of the first isolation portion 22 facing away from the substrate 10, the orthographic projection of the first isolation portion 22 on the substrate 10 being located within the orthographic projection of the second isolation portion 23 on the substrate 10. Therefore, when a light-emitting material is deposited on a side of the isolation structure 20 facing away from the substrate 10, the light-emitting material can be isolated by the isolation structure 20 to form disconnected light-emitting units 30, and there is no need to use a precision mask to prepare the light-emitting units 30, reducing the development and use of precision masks and thereby reducing preparation costs. Furthermore, the light-emitting units 30 are arranged within the isolation openings 21 in a one-to-one manner, thereby reducing carrier crosstalk between the light-emitting units 30 and improving the display effect of the display panel 100. The composition, preparation, etc. of the isolation structure 20 are further described in PCT/CN2023/134518, 202310759370.2, 202310740412.8, 202310707209.0, 202311346196.5, and 202310909421.5, which are incorporated herein by reference.

Each light-emitting unit 30 may include a first electrode 31, a light-emitting functional layer 32, and a second electrode 33 arranged in a stacked manner. The first electrode 31 may be located on a side of the light-emitting functional layer 32 facing away from the substrate 10, and the second electrode 33 is located on a side of the light-emitting functional layer 32 facing the substrate 10. The first electrode 31 overlaps with the first isolation portion 22, enabling the first electrodes 31 of the light-emitting units 30 to be electrically connected via the first isolation portion 22 to form a full-area electrode, and thus ensuring normal light emission of the light-emitting units 30. One of the first electrode 31 and the second electrode 33 may serve as an anode of the light-emitting unit 30, and the other serves as a cathode of the light-emitting unit 30. In the embodiments of the present application, an example, in which the first electrode 31 serve as the cathode of the light-emitting unit 30, and the second electrode 33 serve as the anode of the light-emitting unit 30, is described. It should be noted that the light-emitting functional layer 32 may be formed by stacking film layer structures. By way of example, the light-emitting functional layer 32 may include a hole inject layer (HIL), a hole transport layer (HTL), a light-emitting layer, an electron inject layer (EIL), and an electron transport layer (ETL) arranged in a stacked manner.

The first encapsulation layer includes the encapsulation portions 40 located on the side of the first electrodes 31 facing away from the substrate 10, and the encapsulation portions 40 are arranged within the isolation openings 21 in a one-to-one manner, and the light-emitting units 30 can be independently encapsulated by the encapsulation portions 40, thereby reducing the risk of the light-emitting units 30 being affected by factors such as moisture, and improving the reliability of the display panel 100. Each encapsulation portion 40 includes at least the first sub-portion 41 and the second sub-portion 42, and the first sub-portion 41 covers the first electrode 31 to encapsulate the corresponding light-emitting unit 30. The second sub-portion 42 is located on a side of the first sub-portion 41 facing away from the substrate 10 to cover the first sub-portion 41. Therefore, the light-emitting unit 30 can be further encapsulated by the second sub-portion 42. Moreover, the second sub-portion 42 can protect the first sub-portion 41 from etching damage caused by etching materials in subsequent manufacturing processes, thereby improving the encapsulation effect on the light-emitting unit 30. In addition, the second sub-portion 42 may also limit the first sub-portion 41, enabling the first sub-portion 41 to more securely cover the side of the first electrode 31 facing away from the substrate 10, thereby reducing the risk of separation between the first sub-portion 41 and the first electrode 31, which otherwise could adversely affect the encapsulation effect. The density of the first sub-portion 41 is different from the density of the second sub-portion 42. In particular, the density of the first sub-portion 41 may be greater than or less than the density of the second sub-portion 42, which is not limited in the embodiments of the present application. The density of the first sub-portion 41 is different from the density of the second sub-portion 42, and by reasonably adjusting a density relationship between the first sub-portion 41 and the second sub-portion 42, the performance of the encapsulation portion 40 can be improved.

The plurality of light-emitting units 30 may include red light-emitting units 30, green light-emitting units 30, and blue light-emitting units 30. In particular, as an example in which the preparation of the green light-emitting units 30 follows the preparation of the red light-emitting units 30, due to the omission of a precision mask, during preparation of the red light-emitting units 30, a red light-emitting material and a red encapsulation material corresponding to the red light-emitting units 30 sequentially fall into the isolation openings 21. Subsequently, the red light-emitting material and the red encapsulation material corresponding to part of the isolation openings 21 are selectively etched and removed, and the red light-emitting material and the red encapsulation material corresponding to the other part of the isolation openings 21 is retained to form the red light-emitting units 30 and the encapsulation portions 40 corresponding to the red light-emitting units 30. Subsequently, the green light-emitting units 30 and the encapsulation portions 40 corresponding to the green light-emitting units 30 are prepared. During preparation, a green light-emitting material and a green encapsulation material sequentially fall into the isolation openings 21. Subsequently, the green light-emitting material and the green encapsulation material corresponding to part of the isolation openings 21 are selectively etched and removed, and the green light-emitting material and the green encapsulation material corresponding to the other part of the isolation openings 21 is retained to form the green light-emitting units 30 and the encapsulation portions 40 corresponding to the green light-emitting units 30. During the process of removing the green light-emitting material and the green encapsulation material within the part of the isolation openings 21, the green light-emitting material and the green encapsulation material located on a side of the green light-emitting material facing away from the substrate 10 within the isolation openings 21 corresponding to the red light-emitting units 30 need to be removed, and only the red light-emitting units 30 for emitting red light and the encapsulation portions 40 for encapsulating the red light-emitting units 30 are present within the isolation openings 21 corresponding to the red light-emitting units 30.

It should be understood that after the red encapsulation material falls into the isolation openings 21, part of a red first sub-portion material of the red encapsulation material may be deposited on a sidewall of the first isolation portion 22 facing an isolation opening 21. When the red first sub-portion material has a relatively large thickness, the red first sub-portion material has a large contact area with the first isolation portion 22. During the subsequent selective etching of the red light-emitting material and the red encapsulation material corresponding to the part of the isolation openings 21, part of the red first sub-portion material may remain on the sidewall of the first isolation portion 22 corresponding to the part of the isolation openings 21. Therefore, when the green light-emitting units 30 and the blue light-emitting units 30 are subsequently prepared in the part of the isolation openings 21, the red first sub-portion material remaining on the sidewall of the first isolation portion 22 may affect the overlap yield between the first electrodes 31 of the green light-emitting units 30 and blue light-emitting units 30 and the first isolation portion 22, thereby adversely affecting the performance of the display panel 100.

In view of this, the present application provides a display panel 100, in which the first sub-portions 41 of at least two of the encapsulation portions 40 have different thicknesses. During preparation of the light-emitting units 30 and the encapsulation portions 40, the light-emitting unit 30 and the encapsulation portion 40 corresponding to the first sub-portion 41 with the minimum thickness can be preferentially prepared. This reduces the contact area between the material of the first sub-portion 41 of the previously prepared encapsulation portion 40 and the sidewall of the first isolation portion 22 facing the isolation opening 21, or even prevents contact between the material of the first sub-portion 41 and the sidewall of the first isolation portion 22. Consequently, when subsequently etching and removing the material of the first sub-portion 41 within part of the isolation openings 21, it is easier to etch and remove the material of the first sub-portion 41 within the part of the isolation openings 21, thereby reducing the risk of the material of the first sub-portion 41 remaining on the sidewall of the first isolation portion 22 corresponding to the part of the isolation openings 21 and thus improving the overlap yield between the first electrodes 31 of subsequently prepared light-emitting units 30 and the corresponding first isolation portion 22.

It should be noted that the thickness mentioned in the present application may refer to the minimum thickness, which specifically denotes the minimum distance from a side of a film layer close to the substrate 10 to a side of the film layer away from the substrate 10, i.e., the minimum distance between two surfaces of the film layer along a thickness direction of the substrate 10.

With continued reference to FIG. 1, in some embodiments, the second sub-portion 42 has a thickness greater than the thickness of the first sub-portion 41, thereby further improving the encapsulation effect on the light-emitting unit 30 and the limiting effect on the first sub-portion 41.

In one embodiment, a gap is formed between the side of the first sub-portion 41 facing away from the substrate 10 and a side of the second isolation portion 23 facing the substrate 10, and the gap is filled with the second sub-portion 42.

In particular, the orthographic projection of the first isolation portion 22 on the substrate 10 is located within the orthographic projection of the second isolation portion 23 on the substrate 10, causing the second isolation portion 23 to protrude toward the isolation opening 21 relative to the first isolation portion 22. Therefore, when the first sub-portion 41 is arranged on the side of the first electrode 31 facing away from the substrate 10, a gap is generally present between the first sub-portion 41 and the second isolation portion 23. The gap is filled with the second sub-portion 42, and the second sub-portion 42 is located not only on the side of the first sub-portion 41 facing away from the substrate 10, but also on a side of the first isolation portion 22 facing the isolation opening 21 and the side of the second isolation portion 23 facing the substrate 10. As a result, the second sub-portion 42 is in contact with both the first sub-portion 41 and the isolation structure 20, which can extend the invasion path of external impurities such as moisture, to improve the encapsulation effect on the light-emitting unit 30, and can also improve the structural strength of the second sub-portion 42, reducing the risk of the second sub-portion 42 peeling off. In addition, the gap is filled with the second sub-portion 42, which can prevent etching materials from entering the gap in subsequent manufacturing processes, thereby reducing the contact area between the encapsulation portion 40 and the etching materials in subsequent manufacturing processes, and reducing the etching impact of the etching materials on the encapsulation portion 40.

In one embodiment, the density of the first sub-portion 41 is greater than the density of the second sub-portion 42. This can improve the bonding strength between the first sub-portion 41 and conductive materials such as the first electrode 31, reduce the risk of the first sub-portion 41 peeling off from these conductive materials such as the first electrode 31, and improve the encapsulation effect on the light-emitting unit 30. Alternatively, the density of the first sub-portion 41 is less than the density of the second sub-portion 42. This can improve the bonding strength between the second sub-portion 42 and the isolation structure 20. On the basis of encapsulating the corresponding light-emitting unit 30 by the first sub-portion 41, the corresponding light-emitting unit 30 can be further encapsulated by the higher-density second sub-portion 42, thereby improving the encapsulation effect.

It should be noted that when the density of the first sub-portion 41 is greater than the density of the second sub-portion 42, the material of the first sub-portion 41 is more likely to remain on the sidewall of the first isolation portion 22 facing the isolation opening 21 during preparation of the first sub-portion 41. Therefore, in the embodiments of the present application, the thicknesses of the first sub-portions 41 of at least two of the encapsulation portions 40 are set to be different. During preparation of the light-emitting units 30 and the encapsulation portions 40, the light-emitting unit 30 and the encapsulation portion 40 corresponding to the first sub-portion 41 with the minimum thickness can be preferentially prepared. This reduces the contact area between the material of the first sub-portion 41 of the previously prepared encapsulation portion 40 and the sidewall of the first isolation portion 22 facing the isolation opening 21, or even prevents contact between the material of the first sub-portion 41 and the sidewall of the first isolation portion 22. Consequently, when subsequently etching and removing the material of the first sub-portion 41 within part of the isolation openings 21, it is easier to etch and remove the material of the first sub-portion 41 within the part of the isolation openings 21, thereby reducing the risk of remaining material of the first sub-portion 41 adversely affecting the overlap between the first electrode 31 of the subsequently formed light-emitting unit 30 and the corresponding first isolation portion 22.

In one embodiment, the material of the first sub-portion 41 is the same as the material of the second sub-portion 42, which helps to improve the bonding strength between the first sub-portion 41 and the second sub-portion 42, thereby reducing the risk of separation between the first sub-portion 41 and the second sub-portion 42.

It should be noted that the material of the first sub-portion 41 being the same as the material of the second sub-portion 42 means that both the first sub-portion 41 and the second sub-portion 42 include the same elements, where the proportions of the elements may vary, resulting in different densities between the first sub-portion 41 and the second sub-portion 42.

In one embodiment, the first sub-portion 41 and/or the second sub-portion 42 include an inorganic material. By way of example, the first sub-portion 41 and/or the second sub-portion 42 may be made of materials such as silicon oxide, silicon nitride, or silicon oxynitride, which can provide good mechanical support and the encapsulation protection to prevent the display panel 100 from being affected by the environment. Moreover, the first sub-portion and/or the second sub-portion can further block harmful substances such as external moisture and oxygen from entering the interior of the display panel 100, thereby improving the service life and stability of the display panel 100.

With continued reference to FIG. 1, in some embodiments, the second sub-portion 42 extends to a side of the second isolation portion 23 facing away from the substrate 10 via a sidewall of the second isolation portion 23 facing the isolation opening 21. This can further increase the contact area between the second sub-portion 42 and the isolation structure 20, to extend the invasion path of impurities such as moisture, and can also improve the bonding strength between the second sub-portion 42 and the isolation structure 20, reducing the risk of the second sub-portion 42 peeling off from the isolation structure 20, and thus better encapsulating the light-emitting unit 30.

In one embodiment, the first sub-portion 41 includes a first segment 411, a second segment 412, and a third segment 413, the first segment 411 being located on the side of the first electrode 31 facing away from the substrate 10, the second segment 412 being located on the side of the first isolation portion 22 facing the isolation opening 21, and the third segment 413 being located between the sidewall of the second isolation portion 23 facing the isolation opening 21 and the second sub-portion 42.

The first segment 411 of the first sub-portion 41 is located on the side of the first electrode 31 facing away from the substrate 10, and the second segment 412 thereof is located on the side of the first isolation portion 22 facing the isolation opening 21. That is, part of the first sub-portion 41 extends from the side of the first electrode 31 facing away from the substrate 10 to the sidewall of the first isolation portion 22 facing the isolation opening 21. As a result, the first sub-portion 41 not only covers the first electrode 31 but also covers part of the isolation structure 20, which can extend the invasion path of impurities such as moisture, and can also improve the structural strength of the first sub-portion 41, reducing the risk of the first sub-portion 41 peeling off, and improving the encapsulation effect.

It should be understood that, since the material of the first sub-portion 41 is the same as the material of the second sub-portion 42 and the density of the first sub-portion 41 is greater than the density of the second sub-portion 42, the bonding strength between the third segment 413 and the second sub-portion 42 and the bonding strength between the third segment 413 and the second isolation portion 23 are both superior to the bonding strength between the second sub-portion 42 and the second isolation portion 23. Therefore, in these embodiments, by configuring the first sub-portion 41 to include the third segment 413 located between the sidewall of the second isolation portion 23 facing the isolation opening 21 and the second sub-portion 42, the second sub-portion 42 is connected to the second isolation portion 23 via the third segment 413, which can improves the bonding strength of the second sub-portion 42 and reduce the risk of the second sub-portion 42 peeling off from the isolation structure 20, compared to direct contact between the second sub-portion 42 and the second isolation portion 23.

In one embodiment, the third segment 413 further extends to the side of the second isolation portion 23 facing away from the substrate 10, thereby extending the invasion path between the third segment 413 and the second isolation portion 23 and improving the sealing effect.

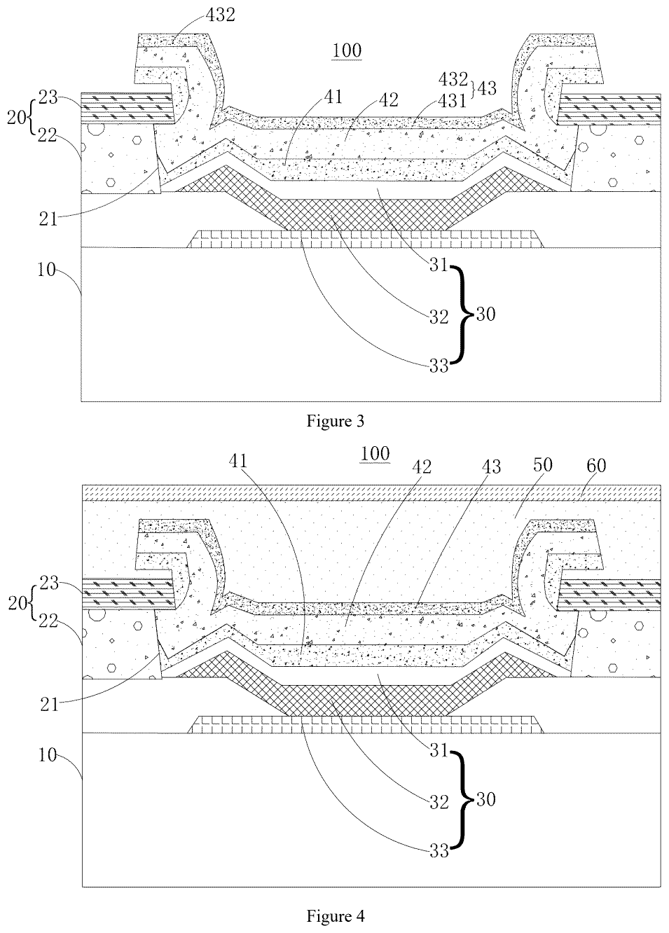

Referring to FIG. 3, in some embodiments, each encapsulation portion 40 further includes a third sub-portion 43, the third sub-portion 43 covering the second sub-portion 42. The third sub-portion 43 can not only encapsulate the light-emitting unit 30 to further improve the encapsulation effect, but can also protect the second sub-portion 42 from etching damage caused by etching materials in subsequent manufacturing processes. In addition, by providing the third sub-portion 43 on a side of the second sub-portion 42 facing away from the substrate 10, the third sub-portion 43 can also limit the second sub-portion 42 and the first sub-portion 41, thereby making the second sub-portion 42 and the first sub-portion 41 more secure.

In one embodiment, the first sub-portion 41, the second sub-portion 42, and the third sub-portion 43 may be made of the same material, for example, silicon oxynitride, or may be made of different materials, for example, silicon nitride for the first sub-portion 41, silicon oxynitride for the second sub-portion 42, and silicon oxide for the third sub-portion 43. The combination is not limited thereto.

In one embodiment, the third sub-portion 43 extends to the side of the second isolation portion 23 facing away from the substrate 10, thereby increasing the contact area between the third sub-portion 43 and the second sub-portion 42 and improving the encapsulation effect.

In one embodiment, the third sub-portion 43 includes a fourth segment 431 and a fifth segment 432, an orthographic projection of the fourth segment 431 on the substrate 10 is located within an orthographic projection of the first electrode 31 on the substrate 10, the fifth segment 432 extends from an edge of the fourth segment 431 to the side of the second isolation portion 23 facing away from the substrate 10, and at least part of the fourth segment 431 protrudes relative to the first isolation portion 22 in a direction away from the substrate 10, and the encapsulation portion 40 has a sufficient thickness to ensure the encapsulation effect on the light-emitting unit 30.

In one embodiment, the density of the first sub-portion 41 is greater than the density of the second sub-portion 42. This can improve the bonding strength between the first sub-portion 41 and conductive materials such as the first electrode 31, and reduce the risk of the first sub-portion 41 peeling off from these conductive materials such as the first electrode 31. Furthermore, the third sub-portion 43 has a density greater than the density of the second sub-portion 42. This can improve the bonding strength between the third sub-portion 43 and the isolation structure 20, to improve the encapsulation effect, and can also improve the etching resistance of the third sub-portion 43, making the third sub-portion 43 less prone to etching damage caused by etching materials in subsequent manufacturing processes, and thus improving the protective effect of the third sub-portion 43 on the second sub-portion 42 and the first sub-portion 41.

In one embodiment, the density of the third sub-portion 43 is greater than or equal to the density of the first sub-portion 41, thereby further improving the etching resistance of the third sub-portion 43.

In one embodiment, the material of the third sub-portion 43 is the same as the material of the second sub-portion 42, which helps to improve the bonding strength between the second sub-portion 42 and the third sub-portion 43, thereby reducing the risk of separation between the second sub-portion 42 and the third sub-portion 43.

In one embodiment, the third sub-portion 43 includes an inorganic material. By way of example, the third sub-portion 43 may be made of materials such as silicon oxide, silicon nitride, or silicon oxynitride, which can provide good mechanical support and the encapsulation protection to prevent the display panel 100 from being affected by the environment. Moreover, the third sub-portion can further block harmful substances such as external moisture and oxygen from entering the interior of the display panel 100, thereby improving the service life and stability of the display panel 100.

Referring to FIG. 2, in some embodiments, the light-emitting units 30 include a first light-emitting unit 301, a second light-emitting unit 302, and a third light-emitting unit 303; the encapsulation portions 40 include a first encapsulation portion 401, a second encapsulation portion 402, and a third encapsulation portion 403; and the first encapsulation portion 401 is configured to encapsulate the first light-emitting unit 301; the second encapsulation portion 402 is configured to encapsulate the second light-emitting unit 302; and the third encapsulation portion 403 is configured to encapsulate the third light-emitting unit 303.

In particular, the first encapsulation portion 401 is located on a side of the first light-emitting unit 301 facing away from the substrate 10 and is configured to encapsulate the first light-emitting unit 301, the second encapsulation portion 402 is located on a side of the second light-emitting unit 302 facing away from the substrate 10 and is configured to encapsulate the second light-emitting unit 302, and the third encapsulation portion 403 is located on a side of the third light-emitting unit 303 facing away from the substrate 10 and is configured to encapsulate the third light-emitting unit 303. In this way, each light-emitting unit 30 is individually encapsulated by each corresponding encapsulation portion 40, thereby improving the encapsulation effect. In one embodiment, the isolation openings 21 include a first isolation opening 21 for receiving the first light-emitting unit 301, a second isolation opening 21 for receiving the second light-emitting unit 302, and a third isolation opening 21 for receiving the third light-emitting unit 303.

In one embodiment, first light-emitting units 301, second light-emitting units 302, and third light-emitting units 303 may be provided. The plurality of first light-emitting units 301 may be prepared and formed in the same process step, the second light-emitting units 302 may be prepared and formed in the same process step, and the third light-emitting units 303 may be prepared and formed in the same process step. In one embodiment, the first light-emitting units 301 may be prepared first, followed by the second light-emitting units 302, and finally the third light-emitting units 303.

Accordingly, first encapsulation portions 401, second encapsulation portions 402, and third encapsulation portions 403 may also be provided. The plurality of first encapsulation portions 401 may be prepared and formed in the same process step, and the first encapsulation portions 401 may be prepared after the preparation and formation of the first light-emitting units 301. The plurality of second encapsulation portions 402 may be prepared and formed in the same process step, and the second encapsulation portions 402 may be prepared after the preparation and formation of the second light-emitting units 302. The plurality of third encapsulation portions 403 may be prepared and formed in the same process step, and the third encapsulation portions 403 may be prepared after the preparation and formation of the third light-emitting units 303.

In one embodiment, the third sub-portion 43 of the first encapsulation portion 401 has a thickness greater than or equal to a thickness of the third sub-portion 43 of the second encapsulation portion 402, and/or the third sub-portion 43 of the second encapsulation portion 402 has a thickness greater than a thickness of the third sub-portion 43 of the third encapsulation portion 403.

It should be understood that, during preparation of the display panel 100, the first light-emitting unit 301 and the first encapsulation portion 401 are first prepared and formed in the first isolation opening 21. Subsequently, the second light-emitting unit 302 and the second encapsulation portion 402 are prepared and formed in the second isolation opening 21, and finally, the third light-emitting unit 303 and the third encapsulation portion 403 are prepared and formed in the third isolation opening 21. During formation of the second light-emitting unit 302 and the second encapsulation portion 402, it is necessary to etch and remove a second light-emitting material and a corresponding encapsulation material located on a side of the first encapsulation portion 401 facing away from the substrate 10. In this process, part of the material of the first encapsulation portion 401 may be synchronously removed. Similarly, during formation of the third light-emitting unit 303 and the third encapsulation portion 403, the etching material for etching a third light-emitting material and a corresponding encapsulation material may cause etching damage to the first encapsulation portion 401 and the second encapsulation portion 402.

Therefore, in these embodiments, the third sub-portion 43 of the first encapsulation portion 401 has a thickness greater than or equal to the thickness of the third sub-portion 43 of the second encapsulation portion 402, and before forming the second light-emitting unit 302 and the second encapsulation portion 402, the greater thickness of the third sub-portion 43 of the first encapsulation portion 401 provides sufficient etching resistance to withstand etching damage caused by etching materials in subsequent manufacturing processes, thereby ensuring the encapsulation reliability of the first encapsulation portion 401. Similarly, the third sub-portion 43 of the second encapsulation portion 402 has a thickness greater than the thickness of the third sub-portion 43 of the third encapsulation portion 403, and before forming the third light-emitting unit 303 and the third encapsulation portion 403, the greater thickness of the third sub-portion 43 of the second encapsulation portion 402 provides sufficient etching resistance to withstand etching damage caused by etching materials in subsequent manufacturing processes, thereby ensuring the encapsulation reliability of the second encapsulation portion 402.

In one embodiment, the first encapsulation portion 401 has a thickness greater than a thickness of the second encapsulation portion 402, and the second encapsulation portion 402 has a thickness greater than a thickness of the third encapsulation portion 403.

It should be noted that the thickness of the first encapsulation portion 401 refers to the sum of the thicknesses of the first sub-portion 41, the second sub-portion 42, and the third sub-portion 43 of the first encapsulation portion 401. The thickness of the second encapsulation portion 402 refers to the sum of the thicknesses of the first sub-portion 41, the second sub-portion 42, and the third sub-portion 43 of the second encapsulation portion 402. The thickness of the third encapsulation portion 403 refers to the sum of the thicknesses of the first sub-portion 41, the second sub-portion 42, and the third sub-portion 43 of the third encapsulation portion 403.

In these embodiments, setting the thickness of the first encapsulation portion 401 to be greater than the thickness of the second encapsulation portion 402 can ensure the encapsulation effect of the first encapsulation portion 401 on the first light-emitting unit 301 and reduce the risk of failure of the first encapsulation portion 401 due to the impact of subsequent manufacturing processes. Similarly, setting the thickness of the second encapsulation portion 402 to be greater than the thickness of the third encapsulation portion 403 can ensure the encapsulation effect of the second encapsulation portion 402 on the second light-emitting unit 302 and reduce the risk of failure of the second encapsulation portion 402 due to the impact of the subsequent manufacturing processes.

With continued reference to FIG. 2, in some embodiments, the light-emitting units 30 include first light-emitting unit 301, a second light-emitting unit 302, and a third light-emitting unit 303; the encapsulation portions 40 include a first encapsulation portion 401, a second encapsulation portion 402, and a third encapsulation portion 403; the first encapsulation portion 401 is configured to encapsulate the first light-emitting unit 301, the second encapsulation portion 402 is configured to encapsulate the second light-emitting unit 302, and the third encapsulation portion 403 is configured to encapsulate the third light-emitting unit 303, where at least two of the first sub-portion 41 of the first encapsulation portion 401, the first sub-portion 41 of the second encapsulation portion 402, and the first sub-portion 41 of the third encapsulation portion 403 have different thicknesses. Therefore, during preparation of the light-emitting units 30 and the encapsulation portions 40, the light-emitting unit 30 and the encapsulation portion 40 corresponding to the first sub-portion 41 with the minimum thickness can be preferentially prepared. This reduces the contact area between the material of the first sub-portion 41 of the previously prepared encapsulation portion 40 and the sidewall of the first isolation portion 22 facing the isolation opening 21, or even prevents contact between the material of the first sub-portion 41 and the sidewall of the first isolation portion 22. Consequently, when subsequently etching and removing the material of the first sub-portion 41 within part of the isolation openings 21, it is easier to etch and remove the material of the first sub-portion 41 within the part of the isolation openings 21, thereby reducing the risk of the material of the first sub-portion 41 remaining on the sidewall of the first isolation portion 22 corresponding to the part of the isolation openings 21 and thus improving the overlap yield between the first electrodes 31 of subsequently prepared light-emitting units 30 and the corresponding first isolation portion 22.

In some embodiments, the thickness of the first sub-portion 41 of the first encapsulation portion 401 and/or of the first sub-portion 41 of the second encapsulation portion 402 is less than the thickness of the first isolation portion 22, and the risk of the material of the first sub-portion 41 of the first encapsulation portion 401 and/or of the first sub-portion 41 of the second encapsulation portion 402 remaining on the sidewall of the first isolation portion 22 corresponding to the subsequently formed third light-emitting unit 303 can be reduced, thereby improving the overlap yield between the first electrode 31 of the subsequently formed third light-emitting unit 303 and the first isolation portion 22.

In one embodiment, a ratio Z1 of the thickness of the first sub-portion 41 of the first encapsulation portion 401 and/or of the first sub-portion 41 of the second encapsulation portion 402 to the thickness of the first isolation portion 22 satisfies: 0.05≤Z1<1. This ensures a reasonable relationship between the thickness of the first sub-portion 41 of the first encapsulation portion 401 and/or of the first sub-portion 41 of the second encapsulation portion 402 and the thickness of the first isolation portion 22, and the first sub-portion 41 of the first encapsulation portion 401 and/or the first sub-portion 41 of the second encapsulation portion 402 exhibits good encapsulation capability, while reducing the risk of the material of the first sub-portion 41 of the first encapsulation portion 401 and/or of the first sub-portion 41 of the second encapsulation portion 402 remaining on the sidewall of the first isolation portion 22 corresponding to the subsequently formed third light-emitting unit 303.

It should be understood that the ratio of the thickness of the first sub-portion 41 of the first encapsulation portion 401 and/or of the first sub-portion 41 of the second encapsulation portion 402 to the thickness of the first isolation portion 22 is greater than or equal to 0.05 and less than 1. For example, this ratio may be 0.05, 0.1, 0.3, 0.5, 0.7, 0.9, 0.95, etc.

With continued reference to FIG. 2, in some embodiments, the thickness of the first sub-portion 41 of the third encapsulation portion 403 is greater than the thickness of the first sub-portion 41 of the first encapsulation portion 401 and/or of the first sub-portion 41 of the second encapsulation portion 402.

In particular, since the third encapsulation portion 403 is prepared after the formation of each light-emitting unit 30, the material of the first sub-portion 41 of the third encapsulation portion 403 does not remain on the sidewall of the first isolation portion 22. Therefore, the thickness of the first sub-portion 41 of the third encapsulation portion 403 can be increased to improve the encapsulation effect of the first sub-portion on the third light-emitting unit 303.

In one embodiment, a ratio Z2 of the thickness of the first sub-portion 41 of the third encapsulation portion 403 to the thickness of the first sub-portion 41 of the first encapsulation portion 401 and/or of the first sub-portion 41 of the second encapsulation portion 402 satisfies: 1<Z2<12, and the first sub-portion 41 of the third encapsulation portion 403 exhibits good encapsulation capability.

It should be noted that the ratio of the thickness of the first sub-portion 41 of the third encapsulation portion 403 to the thickness of the first sub-portion 41 of the first encapsulation portion 401 and/or of the first sub-portion 41 of the second encapsulation portion 402 is greater than 1 and less than or equal to 12. For example, this ratio may be 1.2, 3, 4, 6, 8, 10, 12, etc.

In one embodiment, the thickness of the first sub-portion 41 of the first encapsulation portion 401 is less than or equal to the thickness of the first sub-portion 41 of the second encapsulation portion 402. When the thickness of the first sub-portion 41 of the first encapsulation portion 401 is less than the thickness of the first sub-portion 41 of the second encapsulation portion 402, the first encapsulation portion 401 may be prepared first, followed by the second encapsulation portion 402, reducing the risk of the material of the first sub-portion 41 of the first encapsulation portion 401 remaining in the isolation opening 21 corresponding to the second encapsulation portion 402. When the thickness of the first sub-portion 41 of the first encapsulation portion 401 is equal to the thickness of the first sub-portion 41 of the second encapsulation portion 402, the preparation difficulty of the first sub-portion 41 of the first encapsulation portion 401 and the first sub-portion 41 of the second encapsulation portion 402 can be reduced.

With continued reference to FIG. 2, in some embodiments, a ratio Z3 of the thickness of the first sub-portion 41 of the third encapsulation portion 403 to the thickness of the first isolation portion 22 satisfies: 0.1≤Z3≤1.2. This ensures a reasonable relationship between the thickness of the first sub-portion 41 of the third encapsulation portion 403 and the thickness of the first isolation portion 22, and the third encapsulation portion 403 exhibits good encapsulation capability, to improve the encapsulation effect of the third encapsulation portion on the third light-emitting unit 303.

In one embodiment, the thickness of the first sub-portion 41 of the third encapsulation portion 403 is greater than or equal to the thickness of the first isolation portion 22, thereby further improving the encapsulation capability of the third encapsulation portion 403.

With continued reference to FIG. 2, in some embodiments, the thickness H1 of the first sub-portion 41 of the first encapsulation portion 401 and/or of the first sub-portion 41 of the second encapsulation portion 402 satisfies: 500 angstroms≤H1<5000 angstroms. For example, the thickness of the first sub-portion 41 of the first encapsulation portion 401 and/or of the first sub-portion 41 of the second encapsulation portion 402 may be 500 angstroms, 700 angstroms, 900 angstroms, 2000 angstroms, 3000 angstroms, 5000 angstroms, etc., and the first sub-portion 41 of the first encapsulation portion 401 and/or the first sub-portion 41 of the second encapsulation portion 402 exhibits good encapsulation capability, while reducing the risk of the material of the first sub-portion 41 of the first encapsulation portion 401 and/or of the first sub-portion 41 of the second encapsulation portion 402 remaining on the sidewall of the first isolation portion 22 corresponding to the subsequently formed third light-emitting unit 303.

In one embodiment, the thickness H2 of the first sub-portion 41 of the third encapsulation portion 403 satisfies: 1000 angstroms≤H2≤6000 angstroms. For example, the thickness of the first sub-portion 41 of the third encapsulation portion 403 may be 1000 angstroms, 2000 angstroms, 3000 angstroms, 4000 angstroms, 6000 angstroms, etc., and the first sub-portion 41 of the third encapsulation portion 403 exhibits good encapsulation capability.

In one embodiment, the thickness H3 of the first isolation portion 22 satisfies: 5000 angstroms≤H3≤10000 angstroms. For example, the thickness of the first isolation portion 22 may be 5000 angstroms, 6000 angstroms, 7000 angstroms, 8000 angstroms, 10000 angstroms, etc., to reasonably set the thickness of the first isolation portion 22, improving the isolation effect of the isolation structure 20.

It should be understood that, in the embodiments of the present application, by reasonably setting the thicknesses of the first isolation portion 22, the thicknesses of the first sub-portion 41 of the first encapsulation portion 401 and/or of the first sub-portion 41 of the second encapsulation portion 402, and the thicknesses of the first sub-portion 41 of the third encapsulation portion 403, the material of the first sub-portion 41 of the first encapsulation portion 401 and/or of the first sub-portion 41 of the second encapsulation portion 402 remaining on the sidewall of the first isolation portion 22 can be reduced while ensuing the encapsulation effect of the first sub-portions 41 of the encapsulation portions 40 on the corresponding light-emitting units 30, thereby reducing the risk of the remaining material of the first sub-portion 41 adversely affecting the overlap between the first electrode 31 of the subsequently formed light-emitting unit 30 and the first isolation portion 22.

In some embodiments, a material of the first isolation portion 22 includes a conductive material, enabling the first electrodes 31 of the light-emitting units 30 to be electrically connected via the first isolation portion 22 to form a full-area electrode, and thus ensuring normal light emission of the display panel 100.

In one embodiment, a material of the second isolation portion 23 includes a conductive material, which can reduce the resistivity of the isolation structure 20.

In one embodiment, the isolation structure 20 further includes a third isolation portion located on a side of the first isolation portion 22 facing the substrate 10, and the isolation openings 21 have a greater height difference, thereby facilitating the isolation of the light-emitting material and the encapsulation material.

Referring to FIG. 4, in some embodiments, the display panel 100 further includes a second encapsulation layer 50 arranged on a side of the first encapsulation layer facing away from the substrate 10, thereby further preventing external moisture, oxygen, and the like from entering the interior of the display panel 100.

In one embodiment, the second encapsulation layer 50 includes an organic material. The second encapsulation layer 50 may be made of an organic material such as a polymer. The second encapsulation layer 50 may have a thickness greater than a thickness of the first encapsulation layer, is more flexible, and thus can better adapt to the bending and curvature of the display panel 100. In addition, the organic material can also serve to buffer an external force. In one embodiment, the second encapsulation layer 50 may be prepared by an inkjet printing process, which helps to improve production efficiency and reduce production costs.

In one embodiment, the display panel 100 further includes a third encapsulation layer 60 arranged on a side of the second encapsulation layer 50 facing away from the substrate 10, to further improve the encapsulation effect.

In one embodiment, the third encapsulation layer 60 includes an inorganic material, which can provide good mechanical support and the encapsulation protection to prevent the display panel 100 from being affected by the environment. Moreover, the third encapsulation layer can further block harmful substances such as external moisture and oxygen from entering the interior of the display panel 100.

Referring to FIG. 5, one embodiment of the present application provides a preparation method for a display panel 100, including:
S10, forming an isolation structure 20 on a side of a substrate 10, wherein the isolation structure 20 encloses isolation openings 21, and the isolation structure 20 includes a first isolation portion 22 and a second isolation portion 23 arranged on a side of the first isolation portion 22 facing away from the substrate 10, an orthographic projection of the first isolation portion 22 on the substrate 10 being located within an orthographic projection of the second isolation portion 23 on the substrate 10; and
S20, forming, in the isolation openings 21, light-emitting units 30 and encapsulation portions 40 configured to encapsulate the light-emitting units 30, where each light-emitting unit 30 includes a first electrode 31 overlapping with the first isolation portion 22, and each encapsulation portion 40 includes at least a first sub-portion 41 and a second sub-portion 42, the first sub-portion 41 covering the first electrode 31, the second sub-portion 42 covering the first sub-portion 41, the first sub-portion 41 having a density different from a density of the second sub-portion 42, and the first sub-portions 41 of at least two of the encapsulation portions 40 having different thicknesses.

In these embodiments, the isolation structure 20 is first formed on a side of the substrate 10, where the isolation structure 20 encloses the isolation openings 21, and the isolation structure 20 includes the first isolation portion 22 and the second isolation portion 23 arranged on the side of the first isolation portion 22 facing away from the substrate 10, the orthographic projection of the first isolation portion 22 on the substrate 10 being located within the orthographic projection of the second isolation portion 23 on the substrate 10. Subsequently, the light-emitting units 30 and the encapsulation portions 40 configured to encapsulate the light-emitting units 30 are formed in the isolation openings 21, where each light-emitting unit 30 includes the first electrode 31 overlapping with the first isolation portion 22, and each encapsulation portion 40 includes at least the first sub-portion 41 and the second sub-portion 42, the first sub-portion 41 covering the first electrode 31, the second sub-portion 42 covering the first sub-portion 41, and the first sub-portion 41 having a density different from the density of the second sub-portion 42. The light-emitting unit 30 is encapsulated by both the first sub-portion 41 and the second sub-portion 42 of different densities, thereby improving the encapsulation effect. The first sub-portions 41 of at least two of the encapsulation portions 40 have different thicknesses. During preparation of the light-emitting units 30 and the encapsulation portions 40, the light-emitting unit 30 and the encapsulation portion 40 corresponding to the first sub-portion 41 with the minimum thickness can be preferentially prepared. This reduces the contact area between the material of the first sub-portion 41 of the previously prepared encapsulation portion 40 and the sidewall of the first isolation portion 22 facing the isolation opening 21, or even prevents contact between the material of the first sub-portion 41 and the sidewall of the first isolation portion 22. Consequently, when subsequently etching and removing the material of the first sub-portion 41 within part of the isolation openings 21, it is easier to etch and remove the material of the first sub-portion 41 within the part of the isolation openings 21, thereby reducing the risk of the material of the first sub-portion 41 remaining on the sidewall of the first isolation portion 22 corresponding to the part of the isolation openings 21 and thus improving the overlap yield between the first electrodes 31 of subsequently prepared light-emitting units 30 and the corresponding first isolation portion 22.

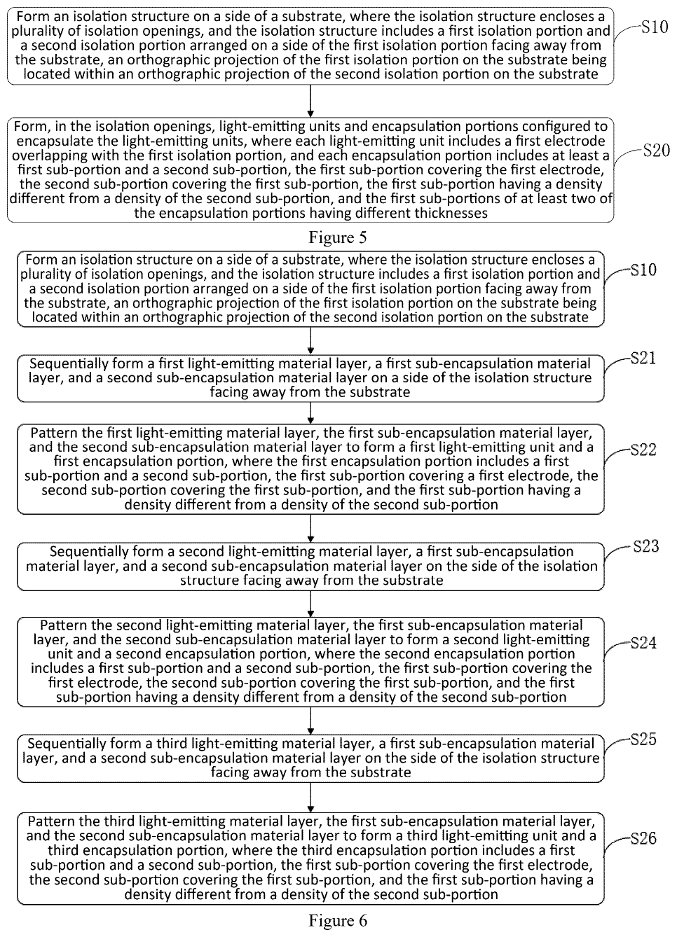

Referring to FIG. 6, in some embodiments, forming, in the isolation openings 21, the light-emitting units 30 and the encapsulation portions 40 configured to encapsulate the light-emitting units 30 includes the following steps.

At S21, a first light-emitting material layer, a first sub-encapsulation material layer, and a second sub-encapsulation material layer are sequentially formed on a side of the isolation structure 20 facing away from the substrate 10. In particular, the first sub-encapsulation material layer is located on a side of the first light-emitting material layer facing away from the substrate 10, and the second sub-encapsulation material layer is located on a side of the first sub-encapsulation material layer facing away from the substrate 10.

At S22, the first light-emitting material layer, the first sub-encapsulation material layer, and the second sub-encapsulation material layer are patterned to form a first light-emitting unit 301 and a first encapsulation portion 401, where the first encapsulation portion 401 includes a first sub-portion 41 and a second sub-portion 42, the first sub-portion 41 covering the first electrode 31, the second sub-portion 42 covering the first sub-portion 41, and the first sub-portion 41 having a density different from a density of the second sub-portion 42. In particular, the first light-emitting material layer, the first sub-encapsulation material layer, and the second sub-encapsulation material layer are patterned, that is, part of the first light-emitting material layer, the first sub-encapsulation material layer, and the second sub-encapsulation material layer are removed, and part of the first light-emitting material layer, the first sub-encapsulation material layer, and the second sub-encapsulation material layer located within the isolation opening 21 and on the side of the isolation structure 20 facing away from the substrate 10 are retained, to form the first light-emitting unit 301 and the first encapsulation portion 401 including the first sub-portion 41 and the second sub-portion 42.

At S23, a second light-emitting material layer, a first sub-encapsulation material layer, and a second sub-encapsulation material layer are sequentially formed on the side of the isolation structure 20 facing away from the substrate 10. The first sub-encapsulation material layer is located on a side of the second light-emitting material layer facing away from the substrate 10, and the second sub-encapsulation material layer is located on a side of the first sub-encapsulation material layer facing away from the substrate 10.

At S24, the second light-emitting material layer, the first sub-encapsulation material layer, and the second sub-encapsulation material layer are patterned to form a second light-emitting unit 302 and a second encapsulation portion 402, where the second encapsulation portion 402 includes a first sub-portion 41 and a second sub-portion 42, the first sub-portion 41 covering the first electrode 31, the second sub-portion 42 covering the first sub-portion 41, and the first sub-portion 41 having a density different from a density of the second sub-portion 42. In particular, the second light-emitting material layer, the first sub-encapsulation material layer, and the second sub-encapsulation material layer are patterned, that is, part of the second light-emitting material layer, the first sub-encapsulation material layer, and the second sub-encapsulation material layer are removed, and part of the second light-emitting material layer, the first sub-encapsulation material layer, and the second sub-encapsulation material layer located within the isolation opening 21 and on the side of the isolation structure 20 facing away from the substrate 10 are retained, to form the second light-emitting unit 302 and the second encapsulation portion 402 including the first sub-portion 41 and the second sub-portion 42.

At S25, a third light-emitting material layer, a first sub-encapsulation material layer, and a second sub-encapsulation material layer are sequentially formed on the side of the isolation structure 20 facing away from the substrate 10. The first sub-encapsulation material layer is located on a side of the third light-emitting material layer facing away from the substrate 10, and the second sub-encapsulation material layer is located on a side of the first sub-encapsulation material layer facing away from the substrate 10.

At S26, the third light-emitting material layer, the first sub-encapsulation material layer, and the second sub-encapsulation material layer are patterned to form a third light-emitting unit 303 and a third encapsulation portion 403, where the third encapsulation portion 403 includes a first sub-portion 41 and a second sub-portion 42, the first sub-portion 41 covering the first electrode 31, the second sub-portion 42 covering the first sub-portion 41, and the first sub-portion 41 having a density different from a density of the second sub-portion 42. In particular, the third light-emitting material layer, the first sub-encapsulation material layer, and the second sub-encapsulation material layer are patterned, that is, part of the third light-emitting material layer, the first sub-encapsulation material layer, and the second sub-encapsulation material layer are removed, and part of the third light-emitting material layer, the first sub-encapsulation material layer, and the second sub-encapsulation material layer located within the isolation opening 21 and on the side of the isolation structure 20 facing away from the substrate 10 are retained, to form the third light-emitting unit 303 and the third encapsulation portion 403 including the first sub-portion 41 and the second sub-portion 42.

In these embodiments, the first light-emitting unit 301 and the first encapsulation portion 401 configured to encapsulate the first light-emitting unit 301 are first formed in a first part of the isolation openings 21. Subsequently, the second light-emitting unit 302 and the second encapsulation portion 402 configured to encapsulate the second light-emitting unit 302 are formed in a second part of the isolation openings 21. Finally, the third light-emitting unit 303 and the third encapsulation portion 403 configured to encapsulate the third light-emitting unit 303 are formed in a third part of the isolation openings 21. In this way, the light-emitting units 30 can be independently encapsulated by the encapsulation portions 40.

In one embodiment, a thickness of the first sub-encapsulation material layer located on the side of the first light-emitting material layer facing away from the substrate 10 may be less than or equal to a thickness of the first sub-encapsulation material layer located on the side of the second light-emitting material layer facing away from the substrate 10, and the thickness of the first sub-encapsulation material layer located on the side of the first light-emitting material layer facing away from the substrate 10 may be less than a thickness of the first sub-encapsulation material layer located on the side of the third light-emitting material layer facing away from the substrate 10, and a thickness of the first sub-portion 41 of the first encapsulation portion 401 is less than or equal to a thickness of the first sub-portion 41 of the second encapsulation portion 402, and the thickness of the first sub-portion 41 of the first encapsulation portion 401 is less than a thickness of the first sub-portion 41 of the third encapsulation portion 403, thereby reducing the risk of the material of the first sub-portion 41 of the first encapsulation portion 401 remaining in the isolation openings 21 corresponding to the second encapsulation portion 402 and the third encapsulation portion 403 during preparation of the first encapsulation portion 401.

In some embodiments, sequentially forming the first light-emitting material layer, the first sub-encapsulation material layer, and the second sub-encapsulation material layer on the side of the isolation structure 20 facing away from the substrate 10 further includes:
forming a third sub-encapsulation material layer on a side of the second sub-encapsulation material layer facing away from the substrate 10.

Patterning the first light-emitting material layer, the first sub-encapsulation material layer, and the second sub-encapsulation material layer to form the first light-emitting unit 301 and the first encapsulation portion 401 further includes:
patterning the third sub-encapsulation material layer to form a third sub-portion 43 located on a side of the second sub-portion 42 facing away from the substrate 10.

Sequentially forming the second light-emitting material layer, the first sub-encapsulation material layer, and the second sub-encapsulation material layer on the side of the isolation structure 20 facing away from the substrate 10 further includes:
forming a third sub-encapsulation material layer on a side of the second sub-encapsulation material layer facing away from the substrate 10.

Patterning the second light-emitting material layer, the first sub-encapsulation material layer, and the second sub-encapsulation material layer to form the second light-emitting unit 302 and the second encapsulation portion 402 further includes:
patterning the third sub-encapsulation material layer to form a third sub-portion 43 located on a side of the second sub-portion 42 facing away from the substrate 10.

Sequentially forming the third light-emitting material layer, the first sub-encapsulation material layer, and the second sub-encapsulation material layer on the side of the isolation structure 20 facing away from the substrate 10 further includes:
forming a third sub-encapsulation material layer on a side of the second sub-encapsulation material layer facing away from the substrate 10.

Patterning the third light-emitting material layer, the first sub-encapsulation material layer, and the second sub-encapsulation material layer to form the third light-emitting unit 303 and the third encapsulation portion 403 further includes:
patterning the third sub-encapsulation material layer to form a third sub-portion 43 located on a side of the second sub-portion 42 facing away from the substrate 10.

In these embodiments, when sequentially forming the first light-emitting material layer, the first sub-encapsulation material layer, and the second sub-encapsulation material layer on the side of the isolation structure 20 facing away from the substrate 10, the third sub-encapsulation material layer is also formed on the side of the second sub-encapsulation material layer facing away from the substrate 10, and when part of the first light-emitting material layer, the first sub-encapsulation material layer, and the second sub-encapsulation material layer are removed, and part of the first light-emitting material layer, the first sub-encapsulation material layer, and the second sub-encapsulation material layer in the isolation opening 21 are retained, part of the third sub-encapsulation material layer is also removed, and part of the third sub-encapsulation material layer in the isolation opening 21 is retained to form the third sub-portion 43 located on the side of the second sub-portion 42 facing away from the substrate 10. In this way, the first light-emitting unit 301 is further encapsulated by the third sub-portion 43, thereby further improving the encapsulation effect. Moreover, the third sub-portion 43 can protect the second sub-portion 42 from etching damage caused by etching materials in subsequent manufacturing processes. In addition, the third sub-portion 43 can also limit the second sub-portion 42 and the first sub-portion 41, thereby making the second sub-portion 42 and the first sub-portion 41 more secure.

Similarly, when sequentially forming the second light-emitting material layer, the first sub-encapsulation material layer, and the second sub-encapsulation material layer on the side of the isolation structure 20 facing away from the substrate 10, the third sub-encapsulation material layer is also formed on the side of the second sub-encapsulation material layer facing away from the substrate 10, and when part of the second light-emitting material layer, the first sub-encapsulation material layer, and the second sub-encapsulation material layer are removed, and part of the second light-emitting material layer, the first sub-encapsulation material layer, and the second sub-encapsulation material layer in the isolation opening 21 are retained, part of the third sub-encapsulation material layer is also removed, and part of the third sub-encapsulation material layer in the isolation opening 21 is retained to form the third sub-portion 43 located on the side of the second sub-portion 42 facing away from the substrate 10. In this way, the second light-emitting unit 302 is further encapsulated by the third sub-portion 43, thereby further improving the encapsulation effect. Moreover, the third sub-portion 43 can protect the second sub-portion 42 from etching damage caused by etching materials in subsequent manufacturing processes. In addition, the third sub-portion 43 can also limit the second sub-portion 42 and the first sub-portion 41, thereby making the second sub-portion 42 and the first sub-portion 41 more secure.

When sequentially forming the third light-emitting material layer, the first sub-encapsulation material layer, and the second sub-encapsulation material layer on the side of the isolation structure 20 facing away from the substrate 10, the third sub-encapsulation material layer is also formed on the side of the second sub-encapsulation material layer facing away from the substrate 10, and when part of the third light-emitting material layer, the first sub-encapsulation material layer, and the second sub-encapsulation material layer are removed, and part of the third light-emitting material layer, the first sub-encapsulation material layer, and the second sub-encapsulation material layer in the isolation opening 21 are retained, part of the third sub-encapsulation material layer is also removed, and part of the third sub-encapsulation material layer in the isolation opening 21 is retained to form the third sub-portion 43 located on the side of the second sub-portion 42 facing away from the substrate 10. In this way, the third light-emitting unit 303 is further encapsulated by the third sub-portion 43, thereby further improving the encapsulation effect. Moreover, the third sub-portion 43 can also limit the second sub-portion 42 and the first sub-portion 41, thereby making the second sub-portion 42 and the first sub-portion 41 more secure.

In some embodiments, only the first encapsulation layer is provided on the light-emitting layer, with different light-emitting layers corresponding to different first encapsulation layers, and at least two of the first encapsulation layers having different thicknesses.

In consideration of the process manufacturing and yield, when only a first encapsulation layer is provided on the light-emitting layer, the thickness of the first encapsulation layer corresponding to the previously evaporated color is reduced, thereby alleviating the problem of etching remaining.

One embodiment of the present application provides a display device, including a display panel 100 according to any one of the above embodiments or a display panel 100 prepared by a preparation method according to any one of the above embodiments. The display device employs all the above embodiments, and therefore has at least all the beneficial effects brought by the above embodiments, which will not be described in detail herein.

The display device may be any device with a display function, for example, a mobile device, such as a mobile phone, a tablet computer, a laptop computer, a palmtop computer, a vehicle-mounted electronic device, a wearable device, an ultra-mobile personal computer (UMPC), a netbook, or a personal digital assistant (PDA), or a non-mobile device, such as a personal computer (PC), a television (TV), a teller machine, or a self-service machine.

Although the embodiments disclosed in the present application are as described above, the content described is the embodiments used to facilitate the understanding of the present application rather than to limit the present disclosure. The present application may make modification and variations to the form and details of embodiments without departing from the spirit and scope disclosed in the present application. However, the scope of protection of the present application shall still be defined by appended claims.

The above descriptions are merely specific embodiments of the present application. For convenience and conciseness of description, for replacement of other connection manners described above, reference may be made to the corresponding processes in the foregoing method embodiments, which will not be described in detail herein. It should be understood that the scope of protection of the present application is not limited thereto, any equivalent modification or replacement that can be easily conceived within the scope disclosed in the present application fall within the scope of protection of the present application.

1. A display panel, comprising:
a substrate;
an isolation structure arranged on a side of the substrate and enclosing a plurality of isolation openings;
a light-emitting layer comprising light-emitting units at least partially located within the isolation openings;
first electrodes arranged on a side of the light-emitting units facing away from the substrate, a first electrode overlapping with a first isolation portion; and
a first encapsulation layer comprising encapsulation portions located on a side of the first electrodes facing away from the substrate, each encapsulation portion comprising a first sub-portion formed of an inorganic material, the first sub-portion covering the first electrode, and the first sub-portions of at least two of the encapsulation portions having different thicknesses.

2. The display panel of claim 1, wherein each encapsulation portion comprises at least the first sub-portion and a second sub-portion, the second sub-portion covering the first sub-portion.

3. The display panel of claim 2, wherein the second sub-portion has a thickness greater than the thickness of the first sub-portion; and
the isolation structure comprises the first isolation portion and a second isolation portion arranged on a side of the first isolation portion facing away from the substrate, an orthographic projection of the first isolation portion on the substrate being located within an orthographic projection of the second isolation portion on the substrate.

4. The display panel of claim 3, wherein the second sub-portion extends to a side of the second isolation portion facing away from the substrate via a sidewall of the second isolation portion facing an isolation opening.

5. The display panel of claim 4, wherein the first sub-portion comprises a first segment, a second segment, and a third segment, the first segment being located on the side of the first electrode facing away from the substrate, the second segment being located on a side of the first isolation portion facing the isolation opening, and the third segment being located between the sidewall of the second isolation portion facing the isolation opening and the second sub-portion.

6. The display panel of claim 1, wherein each encapsulation portion further comprises a third sub-portion, the third sub-portion covering a second sub-portion.

7. The display panel of claim 6, wherein the plurality of light-emitting units comprise a first light-emitting unit, a second light-emitting unit, and a third light-emitting unit;
a plurality of encapsulation portions comprise a first encapsulation portion, a second encapsulation portion, and a third encapsulation portion; and
the first encapsulation portion is configured to encapsulate the first light-emitting unit, the second encapsulation portion is configured to encapsulate the second light-emitting unit, and the third encapsulation portion is configured to encapsulate the third light-emitting unit.

8. The display panel of claim 1, wherein the plurality of light-emitting units comprise a first light-emitting unit, a second light-emitting unit, and a third light-emitting unit;
a plurality of encapsulation portions comprise a first encapsulation portion, a second encapsulation portion, and a third encapsulation portion; and
the first encapsulation portion is configured to encapsulate the first light-emitting unit, the second encapsulation portion is configured to encapsulate the second light-emitting unit, and the third encapsulation portion is configured to encapsulate the third light-emitting unit, wherein at least two of the first sub-portion of the first encapsulation portion, the first sub-portion of the second encapsulation portion, and the first sub-portion of the third encapsulation portion have different thicknesses.

9. The display panel of claim 8, wherein the thickness of the first sub-portion of the first encapsulation portion and/or of the first sub-portion of the second encapsulation portion is less than a thickness of the first isolation portion.

10. The display panel of claim 8, wherein the thickness of the first sub-portion of the third encapsulation portion is greater than the thickness of the first sub-portion of the first encapsulation portion and/or of the first sub-portion of the second encapsulation portion.

11. The display panel of claim 8, wherein a ratio Z3 of the thickness of the first sub-portion of the third encapsulation portion to a thickness of the first isolation portion satisfies: 0.1≤Z3≤1.2.

12. The display panel of claim 8, wherein the thickness H1 of the first sub-portion of the first encapsulation portion and/or of the first sub-portion of the second encapsulation portion satisfies: 500 angstroms≤H1≤5000 angstroms.

13. The display panel of claim 1, wherein a material of the first isolation portion comprises a conductive material.

14. The display panel of claim 1, further comprising a second encapsulation layer arranged on a side of the first encapsulation layer facing away from the substrate.

15. A preparation method for a display panel, comprising:
forming an isolation structure on a side of a substrate, wherein the isolation structure encloses a plurality of isolation openings, and the isolation structure comprises a first isolation portion and a second isolation portion arranged on a side of the first isolation portion facing away from the substrate, an orthographic projection of the first isolation portion on the substrate being located within an orthographic projection of the second isolation portion on the substrate; and
forming, in the isolation openings, light-emitting units and encapsulation portions configured to encapsulate the light-emitting units, wherein each light-emitting unit comprises a first electrode overlapping with the first isolation portion, and each encapsulation portion comprises at least a first sub-portion and a second sub-portion, the first sub-portion covering the first electrode, the second sub-portion covering the first sub-portion, the first sub-portion having a density different from a density of the second sub-portion, and the first sub-portions of at least two of the encapsulation portions having different thicknesses.

16. The preparation method of claim 15, wherein forming, in the isolation openings, the light-emitting units and the encapsulation portions configured to encapsulate the light-emitting units comprises:
sequentially forming a first light-emitting material layer, a first sub-encapsulation material layer, and a second sub-encapsulation material layer on a side of the isolation structure facing away from the substrate;
patterning the first light-emitting material layer, the first sub-encapsulation material layer, and the second sub-encapsulation material layer to form a first light-emitting unit and a first encapsulation portion, wherein the first encapsulation portion comprises a first sub-portion and a second sub-portion, the first sub-portion covering the first electrode, the second sub-portion covering the first sub-portion, and the first sub-portion having a density different from a density of the second sub-portion;
sequentially forming a second light-emitting material layer, a first sub-encapsulation material layer, and a second sub-encapsulation material layer on the side of the isolation structure facing away from the substrate;
patterning the second light-emitting material layer, the first sub-encapsulation material layer, and the second sub-encapsulation material layer to form a second light-emitting unit and a second encapsulation portion, wherein the second encapsulation portion comprises a first sub-portion and a second sub-portion, the first sub-portion covering the first electrode, the second sub-portion covering the first sub-portion, and the first sub-portion having a density different from a density of the second sub-portion; sequentially forming a third light-emitting material layer, a first sub-encapsulation material layer, and a second sub-encapsulation material layer on the side of the isolation structure facing away from the substrate; and
patterning the third light-emitting material layer, the first sub-encapsulation material layer, and the second sub-encapsulation material layer to form a third light-emitting unit and a third encapsulation portion, wherein the third encapsulation portion comprises a first sub-portion and a second sub-portion, the first sub-portion covering the first electrode, the second sub-portion covering the first sub-portion, and the first sub-portion having a density different from a density of the second sub-portion.

17. The preparation method of claim 16, wherein thicknesses of the first sub-encapsulation material layers corresponding to the first light-emitting material layer and the second light-emitting material layer are less than a thickness of the first sub-encapsulation material layer corresponding to the third light-emitting material layer.

18. The preparation method of claim 17, wherein sequentially forming the first light-emitting material layer, the first sub-encapsulation material layer, and the second sub-encapsulation material layer on the side of the isolation structure facing away from the substrate further comprises:
forming a third sub-encapsulation material layer on a side of the second sub-encapsulation material layer facing away from the substrate;
patterning the first light-emitting material layer, the first sub-encapsulation material layer, and the second sub-encapsulation material layer to form the first light-emitting unit and the first encapsulation portion further comprises:
patterning the third sub-encapsulation material layer to form a third sub-portion located on a side of the second sub-portion facing away from the substrate;
sequentially forming the second light-emitting material layer, the first sub-encapsulation material layer, and the second sub-encapsulation material layer on the side of the isolation structure facing away from the substrate further comprises:
forming a third sub-encapsulation material layer on a side of the second sub-encapsulation material layer facing away from the substrate;
patterning the second light-emitting material layer, the first sub-encapsulation material layer, and the second sub-encapsulation material layer to form the second light-emitting unit and the second encapsulation portion further comprises:
patterning the third sub-encapsulation material layer to form a third sub-portion located on a side of the second sub-portion facing away from the substrate;
sequentially forming the third light-emitting material layer, the first sub-encapsulation material layer, and the second sub-encapsulation material layer on the side of the isolation structure facing away from the substrate further comprises:
forming a third sub-encapsulation material layer on a side of the second sub-encapsulation material layer facing away from the substrate; and
patterning the third light-emitting material layer, the first sub-encapsulation material layer, and the second sub-encapsulation material layer to form the third light-emitting unit and the third encapsulation portion further comprises:
patterning the third sub-encapsulation material layer to form a third sub-portion located on a side of the second sub-portion facing away from the substrate.

19. The preparation method of claim 18, wherein thicknesses of the third sub-encapsulation material layers corresponding to the first light-emitting material layer and the second light-emitting material layer are greater than a thickness of the third sub-encapsulation material layer corresponding to the third light-emitting material layer.

20. A display device, comprising:
a substrate;
an isolation structure arranged on a side of the substrate and enclosing a plurality of isolation openings;
a light-emitting layer comprising light-emitting units at least partially located within the isolation openings;
first electrodes arranged on a side of the light-emitting units facing away from the substrate, a first electrode overlapping with a first isolation portion; and
a first encapsulation layer comprising encapsulation portions located on a side of the first electrodes facing away from the substrate, each encapsulation portion comprising a first sub-portion formed of an inorganic material, the first sub-portion covering the first electrode, and the first sub-portions of at least two of the encapsulation portions having different thicknesses.
